(19) United States
(12) Patent Application Publication
(10) Pub. No.: US 2008/0087972 A1
(43) Pub. Date: Apr. 17, 2008

(54) Copper Doped Magnetic Semiconductors

(75) Inventors: Venkat Rao, Stockholm (SE); Parmanand Sharma, Delhi (IN); Amita Gupta, Kurukshetra (IN)

Correspondence Address: LADAS & PARRY LLP, 224 SOUTH MICHIGAN AVENUE, SUITE 1600, CHICAGO, IL, 60604, US

(73) Assignee: NM SPINTRONECS AB, Lund (SE)

(21) Appl. No.: 11/578,437

(22) PCT Filed: May 17, 2005
(86) PCT No.: PCT/SE05/00711

§ 371 Date: Oct. 12, 2006

(30) Foreign Application Priority Data
May 18, 2004 (SE) 0401320-7

(51) Int. Cl. H01L 29/82; H01L 21/00

(52) U.S. Cl. 257/421; 438/3; 257/E29.323; 257/E21.001

(57) ABSTRACT

A semi-conducting material, a method for producing the material, and ways of implementing the material, wherein said material is doped with Cu or CuO, and is ferromagnetic at least at one temperature in the range between −55° C. and 125° C. Typically the material may comprise GaP or GaN.

### FIELD OF INVENTION

Materials used for electronic components which use ferromagnetism in its function. These types of components are affecting or rectifying the spin orientation of bosons and fermions, e.g. electrons. Search for ferromagnetism above room temperatures in dilute magnetic semiconductors has been a quest in recent years especially to develop potentially rich new class of future devices which exploit the electron spin state i.e. spintronics. The types of components for these

devices include e.g. magnetic memories (e.g. hard discs), semiconductor magnetic memories (e.g. MRAM), spin valve transistors, spin light emitting diodes, non-volatile memory, logic devices, quantum computers, optical isolators, sensors and ultra-fast optical switches. Dilute magnetic semiconductors can also be used in electronic-, and magnetic -based products.

### DESCRIPTION OF RELATED ART

Electronic component technologies are increasingly interested in using ferromagnetic materials for new component designs and functions. Traditional ferromagnetic materials are e.g. iron, nickel, cobalt and their alloys. Novel scientific activities and new suggestions for implementing them, are

frequently being reported in technical and scientific journals. Some examples of materials expectations with basic component designs can be found in recent review articles in Physics World, (April 1999) and IEEE Spectrum, (December 2001). All these documentations describe the problem and needs in designing ferromagnetic materials that can operate at the industrial, automotive and military temperature range (normally −55° C. to 125° C.).

Most of the materials of interest known today require cryogenic temperatures. However Klaus H. Ploog described in Physical Review Letters, July 2001, the use of a film of iron grown on Gallium Arsenide (GaAs) to polarize the spin of electrons injected into semiconducting GaAs. This experiment was carried out at room temperature.

Spintronic devices such as spin valve transistors, spin light emitting diodes, non-volatile memory, logic devices, optical isolators and ultra-fast optical switches are some of the areas of high interest for introducing the ferromagnetic properties at room temperature in a semiconductor described in the two documents (reference 6-7).

In recent years there have been intense search for materials exhibiting ferromagnetic ordering in doped dilute magnetic semiconductors (DMS), described in the following five documents (reference 1-5), focusing on possible spin transport properties which has many potentially interesting device applications.

Among the materials reported so far, Mn-doped GaAs has been found to be ferromagnetic with the highest reported (se reference 1) Curie temperature, Tc˜110 K. Following this Dietl et al. (see reference 2) predicted on a theoretical basis that ZnO and GaN would exhibit ferromagnetism above room temperature on doping with Mn. This prediction initiated intensive experimental work on a variety of doped dilute magnetic semiconductors. Recently, Tc above room temperature has been reported in Co-doped TiO₂, ZnO, and GaN respectively (se reference 3, 8, 9). However, in the Ti₁₋ₓCoₓO sample inhomogeneous clustering of Co was found (see reference 10). Kim et al (see reference 11) showed that while homogeneous films of Zn₁₋ₓCoₓO exhibited a spin-glass behaviour, room temperature ferromagnetism was found in inhomogeneous films attributing the observation to the presence of Co clusters. Clearly, for device applications we need homogeneous films.

We have earlier made an patent application for manganese doped Zinc Oxide.

### SUMMARY OF INVENTION

The invention is based on the concept to incorporate ferromagnetism, into doped dilute magnetic semiconductors by doping with Copper. These ferromagnetic semiconductor materials can operate at the industrial, automotive and military temperature range (normally −55° C. to above 125° C.). Copper is giving rise to magnetic coupling based on a carrier modification effect. This application is showing several semiconductor materials which are becoming ferromagnetic when doped with copper. The copper doping can also improve the magnetic strength in semiconductor materials which are already ferromagnetic e.g. Manganese doped Zinc Oxide.

The invention describes the mechanism of doping by copper. In the application result are shown for some of the materials. Examples of Copper doped materials, giving rise to ferromagnetism, are Copper doped Gallium Phosphide, GaP, Copper doped Gallium Nitride, GaN, Copper doped Gallium Arsenide GaAs, Copper doped Cadmium Sulphide CdS, Copper doped Cadmium Selenide, CdSe, Copper doped Zinc Oxide, ZnO, Copper doped Zinc Sulphide, ZnS, Copper doped Zinc Selenide, ZnSe and Copper doping of Manganese doped Zinc Oxid, ZnMnO, Copper doping of Manganese doped Cadmium Sulphide, CdMnS, Copper doping of Manganese doped Cadmium Selenide, CdMnSe, Copper doping of Manganese doped Zinc Sulphide, ZnMnS, Copper doping of Manganese doped Zinc Selenide, ZnMnSe, . We can see signs of magnetic behavior also in other semiconductors when doped with Copper.

### BRIEF DESCRIPTION OF DRAWINGS AND DIAGRAMS

FIG. 1 illustrates X-ray powder diffraction spectra for GaP:Cu;

FIG. 2 illustrates Raman spectra of the transverse optical (TO)mode and longitudinal optic (LO) mode in doped and undoped GaP:Cu, indicating Cu results in hole-doping;

FIG. 3 illustrates DC magnetization hysteretic data at various temperatures as indicated;

FIG. 4 illustrates temperature dependence of the magnetization for GaP:Cu using a SQUID. The continuous line is a T^{3/2} Bloch-law fit to the T-dependence;

FIG. 5 illustrates temperature dependence of the magnetic coercivity. The line through the data is a fit to an exponential decay equation;

FIG. 6 illustrates FMR spectrum for GaP:Cu at room temperature. Absorption A is the low field non resonant absorption which exists in the ferromagnetic state. Line B is the ferromagnetic resonance absorption, and line c is likely to arise form unreacted CuO in the sample;

FIG. 7 illustrates FMR at (a) 300K, and (b) 138K;

FIG. 8 illustrates temperature dependence of field position of ferromagnetic resonance above room temperature showing the existence of ferromagnetism up to 524K;

FIG. 9 illustrates the effect of Cu on the Magnetic properties of Mn doped ZnO;

FIG. 10 also illustrates the effect of Cu on the Magnetic properties of Mn doped ZnO;

FIG. 11 illustrates the effect of adding Cu on the room temperature magnetic properties of 1 at % Mn doped ZnO. Ms is enhanced by almost 100%;

FIG. 12 illustrates the effect of addition 6 at % Cu to GaN: renders GaN ferromagnetic at room temperature;

FIG. 13 illustrates calculated density or states of Cu doped ZnO showing the ferromagnetic property induced at the Cu site;

FIG. 14 illustrates FMR spectra for Cu doped GaN: evidence for ferromagnetism at room temperature. The blip around 3000 Oe arises from unreacted CuO

FIG. 15 illustrates temperature dependence of the field position of the FMR showing that ferromagnetism exists much above room temperature

FIG. 16 illustrates FMR line width for Cupper doped GaN showing that the ferromagnetism exists much above room temperature.

### DESCRIPTION OF THE PREFERRED EMBODIMENT

This invention is based on the concept to develop ferromagnetism in doped dilute magnetic semiconductors by doping Copper into semiconductor materials that are not ferromagnetic or contain a weak ferromagnetic component. Our experiment shows successful tailoring of ferromagnetism above room temperature in bulk or film layers. The film layers can be created by e.g. laser deposition, sputtering etc.

The invention, with Copper doping, creates ferromagnetism well above room temperature in Gallium Phosphide doped with Cu2+ is detected by ferromagnetic resonance, SQUID magnetometry and neutron diffraction' which clearly shows the ferromagnetism is associated with the GaP lattice and is not from impurity phases. Other important features of the results are the high Curie temperature above 700 K significantly higher than previous observations, the relatively simple low temperature bulk sintering process used to synthesize the material which will significantly reduce cost of large scale.

5 The origin of the ferromagnetism in these alloys is a subject of current research. It has been proposed that the exchange interaction between the dopant spins is mediated by the holes or electrons. 6 In the ferromagnetic state there is a splitting of the valence and conducting band depending on the spin orientation of the charge carriers. The model predicts that hole doped semiconductors will have higher Curie temperatures than electron doped materials.

Manganese may not be the best choice for a dopant. At concentrations above 6 at % Mn. Manganese clusters have been shown to be ferromagnetic motivating the suggestion that the ferromagnetism observed in the doped semiconductors arises from manganese clusters. 7, 8 Also there is the added problem of the possible formation of GaMn and MnP during the synthesis which are known to be ferromagnetic at high temperatures. 9 In order to circumvent these difficulties we have chosen copper as the dopant. There is no evidence of ferromagnetism in bulk copper or copper clusters. Also CuO is known to be an antiferromagnet below 200K. In addition no known ferromagnetic alloys such as CuP or GaCu. Cu has a charge of 2+ and will be a hole dopant. GaP has a number of advantages for a potential magnetic semiconductor. It is a component in AlGaInP used in light emitting diodes and high speed electronics and its lattice parameters are close to silicon perhaps enabling an integration of dilute magnetic semiconductors with conventional silcon circuitry. Here we report SQUID magnetometry, Ferrromagnetic Resonance (FMR) and neutron diffraction evidence for ferromagnetism well above room temperature in copper doped gallium phosphide. Important features of the observation are the relatively simple sintering process for making the material and significantly higher Curie temperature compared to previous observations.

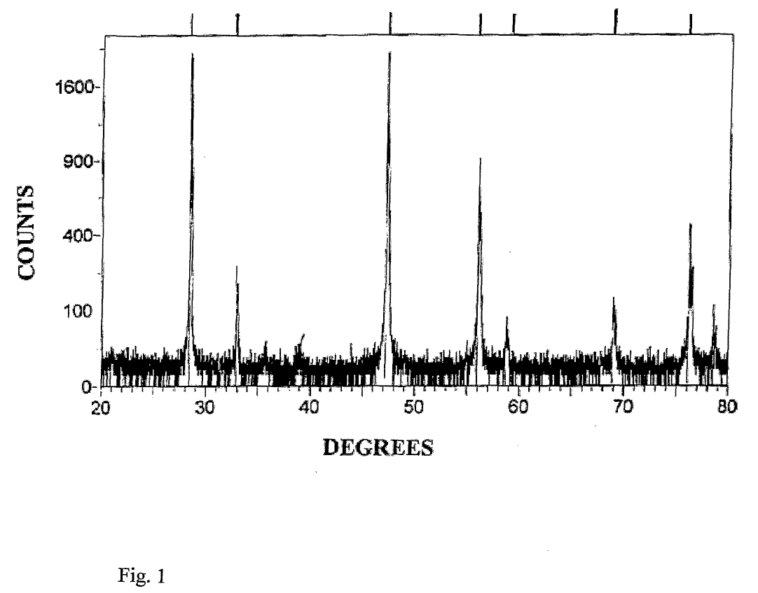

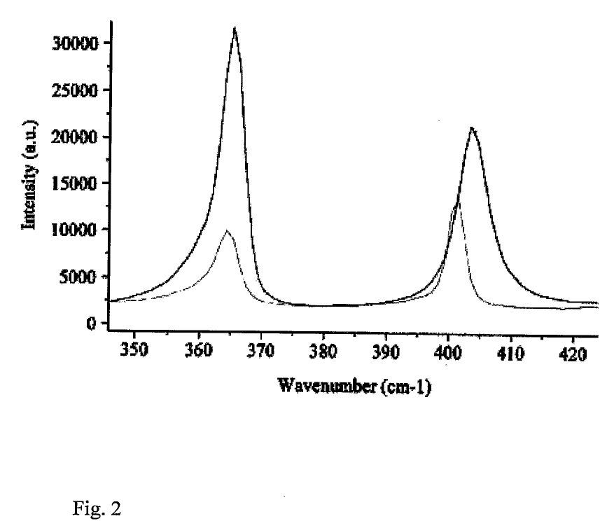

The samples were synthesized by thoroughly mixing in the ratio .03 molecular weight CuO to one molecular weight of 99.999% pure gallium phosphide obtained from Alfa Aesar and then grinding the mixture using a mortar and pestle. The GaP used was examined by electron paramagnetic resonance (EPR) prior to processing to insure no magnetic impurities were present in the material. No evidence for any magnetic impurities were found. EPR is sensitive to magnetic species to one part per ten billion. The samples in the form of pressed pellets contained in an alumina boat were sintered at 500 C in an oven for four hours in air followed by rapid quenching to room temperature. The sintered samples were examined by x ray diffraction employing a Scintag x ray instrument using the Cu K alpha line. FIG. 1 shows the powder X ray diffraction spectra. The lines at the top of the figure are those expected for pure gallium phosphide. The peaks in the doped sample occur at the same scattering angles as pure GaP and no impurity lines are evident in the data. The sintered samples were also examined by Induction Coil Plasma mass spectrometry (ICP-MS) which showed no magnetic metals at levels above 2 parts per billion. The presence of copper in the samples was however detected. FIG. 2 shows the Raman spectra of the transverse optical (TO) mode and longitudinal optic (LO) mode in doped and undoped GaP recorded using a JY Horiba confocal Raman spectrometer. The higher frequency LO mode is down shifted by 3 cm-1 in the copper doped sample. It has been shown in other semiconductors such as GaN that the LO mode is coupled to the plasma mode whose frequency is proportional to the electron carrier concentration. 10 The LO mode has been shown to shift with electron carrier concentration. The observed decrease in the frequency of the LO mode in the Cu doped GaP indicates a decrease in the electron carrier concentration consistent with hole doping.

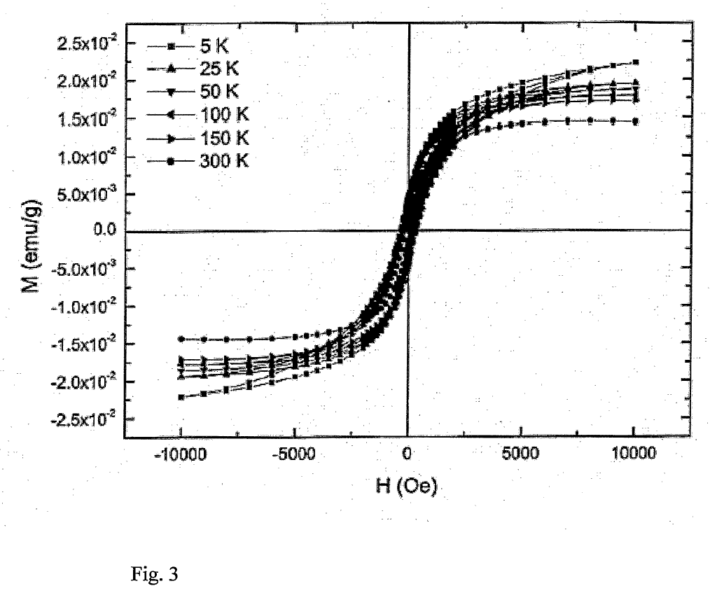

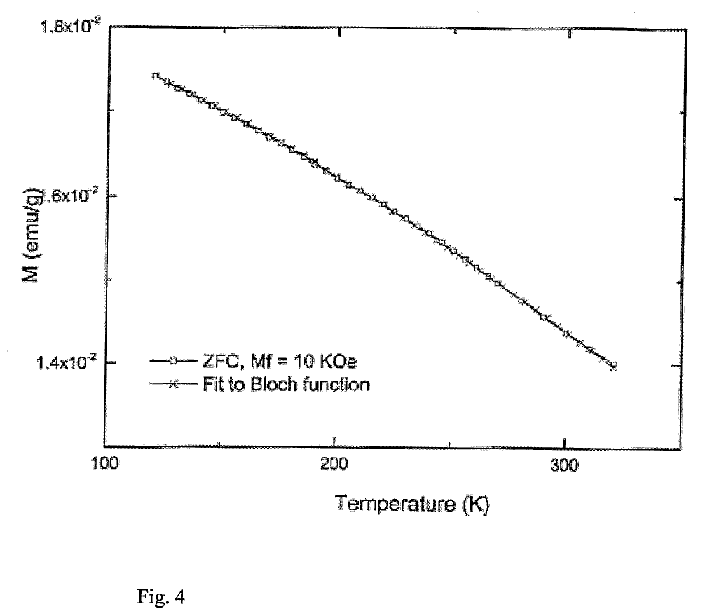

FIG. 3 shows SQUID MPMS2 measurements of the dc magnetic field dependence of the magnetization at a number of temperatures. The saturation magnetization at 300 K is 1.5×10−2 emu/g. The coercivity at room temperature is 125 Oe. FIG. 4 is the temperature dependence of the magnetization at 10 KOe. The line through the data is a fit to the Bloch equation.

M(T)=M(0)(1−AT3/2) (1)

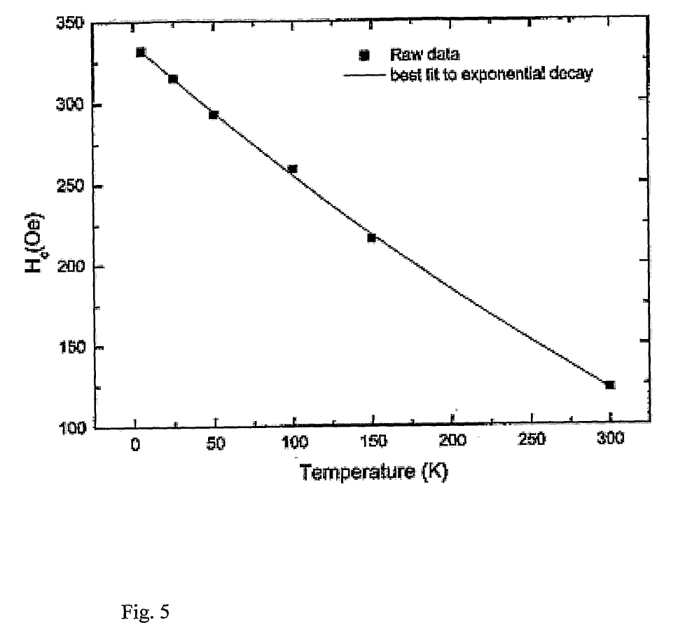

For A=4.0×10−5 K−3/2 and M(0)=18.44 memu/g. These values indicate a high Curie temperature well above 700 K. FIG. 5 is a plot of the temperature dependence of the coercivity . The line through the data is a fit to the exponential decay.

Hc=Hco+Bexp(−T/C) (2)

For Hco=298.38 Oe, B=137.07 Oe and C=728.97 K.

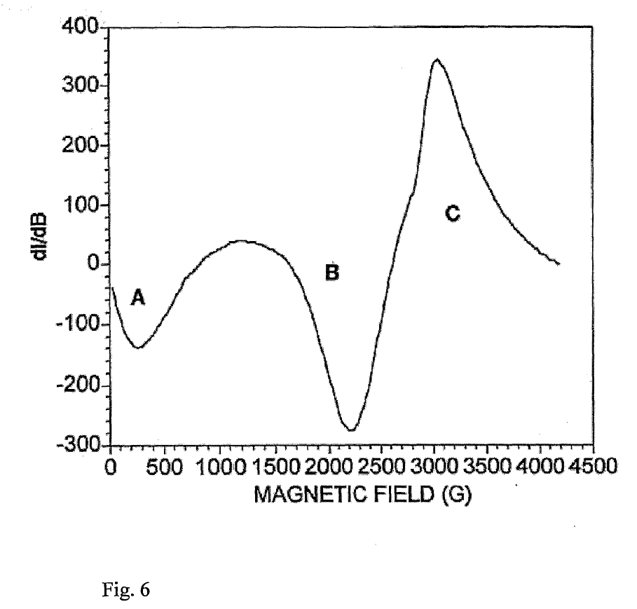

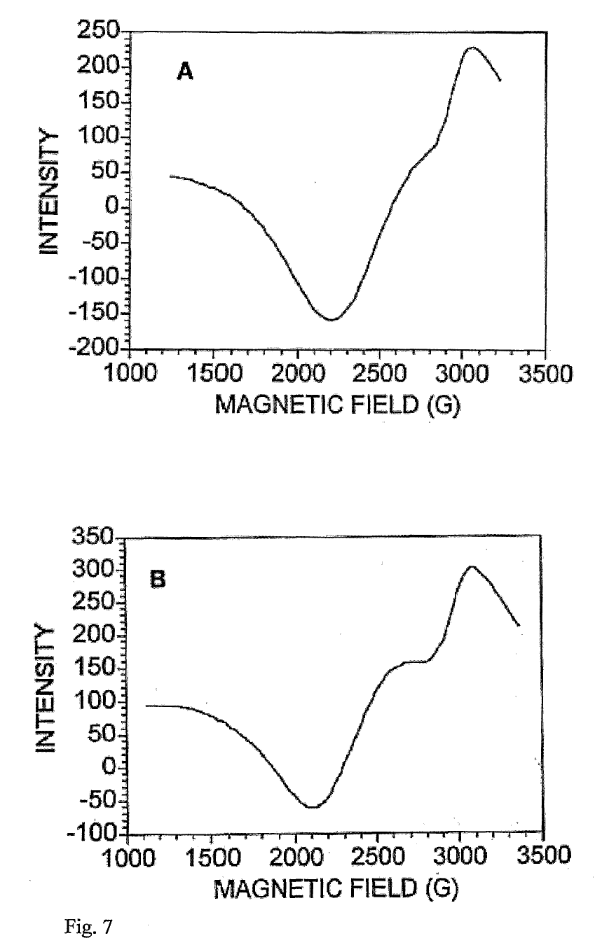

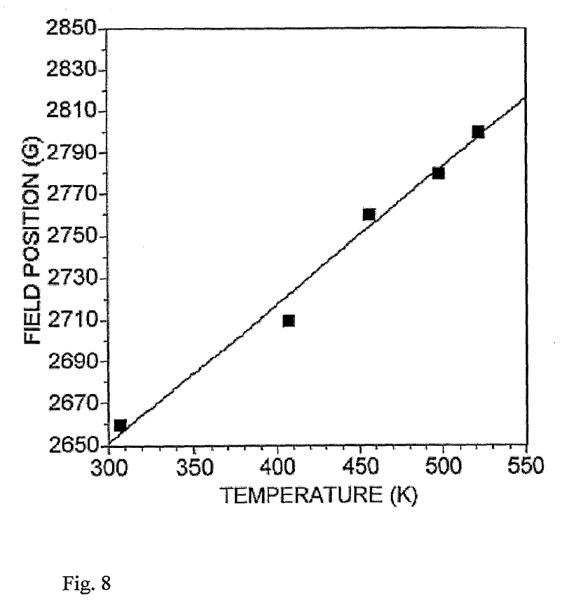

The samples have also been examined by ferromagnetic resonance (FMR) which is a highly sensitive method for verifying the existence of ferromagnetism. 11. FIG. 6 shows the FMR spectrum at 300 K recorded using a Varian E-9 spectrometer operating at 9.2 GHz. Three lines are evident in the spectrum, a low field non resonant signal (A), a ferromagnetic resonance signal (B) and a component (C) which is likely due to some unreacted CuO in the sample. It should be noted that CuO is not ferromagnetic and can not be the source of the ferromagnetism observed here. 12 The presence of the low field non resonant absorption signal is a well established indication of ferromagnetism in materials. 13, 14 The signal occurs because the permeability in the ferromagnetic state depends on the applied magnetic field increasing at low fields to a maximum and then decreasing. Since the surface resistance depends on the square root of the permeability, the microwave absorption depends non-linearly on the strength of the dc magnetic field resulting in a non-resonant derivative signal centered at zero field. This signal is not present in the paramagnetic state and emerges as the temperature is lowered to below Tc. We have been able to observe the low field non resonant absorption at temperatures as high as 524 K the upper limit of our temperature apparatus in the resonance experiment. The characteristic distinguishing FMR signals from EPR signals is a strong temperature dependence of the field position and line width of the resonance on temperature. FIG. 7 shows the FMR spectra at 300 K (a) and at 118 K (b) showing the large shift to lower dc magnetic field at low temperature. FIG. 8 gives the temperature dependence of the field position of the line above room temperature showing that the material is still ferromagnetic at 524 K. Above the Curie temperature the FMR signal becomes an EPR signal of Cu+2 having a field position independent of temperature corresponding to that of spectra c in FIG. 6 which is 2940 G . Extrapolating the data in FIG. 8 to this value allows an estimate of Tc of 739 K.

In summary we have presented clear evidence from SQUID magnetometry, ferromagnetic resonance and neutron diffraction measurements that copper doped gallium phosphide made by a simple sintering process is ferromagnetic at temperatures much higher than any previously reported dilute magnetic semiconductor.

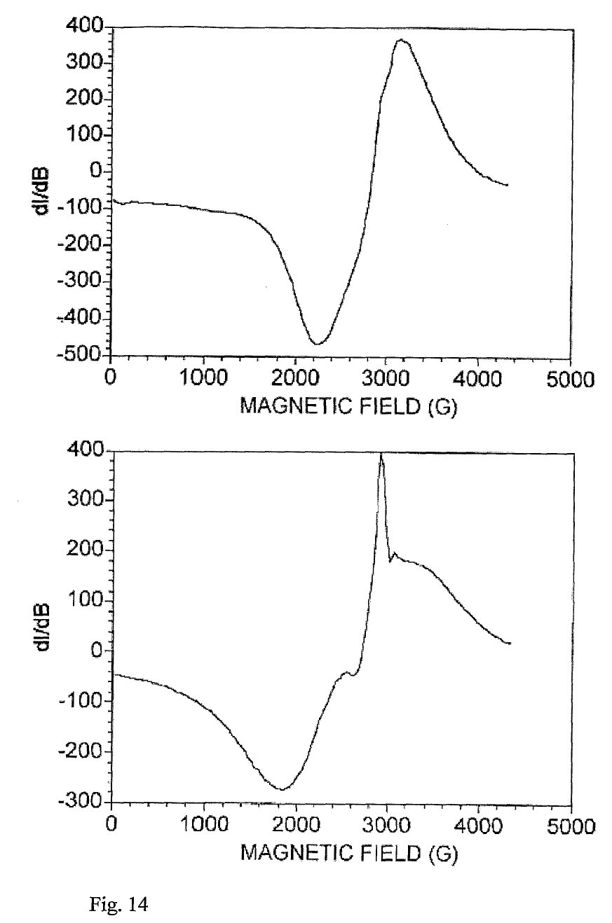

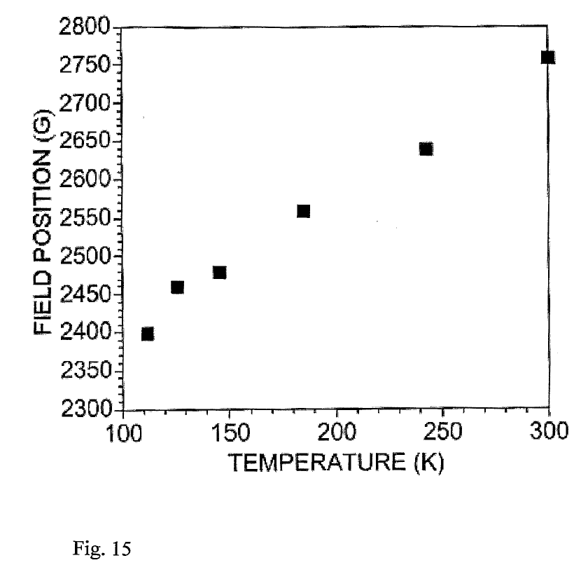

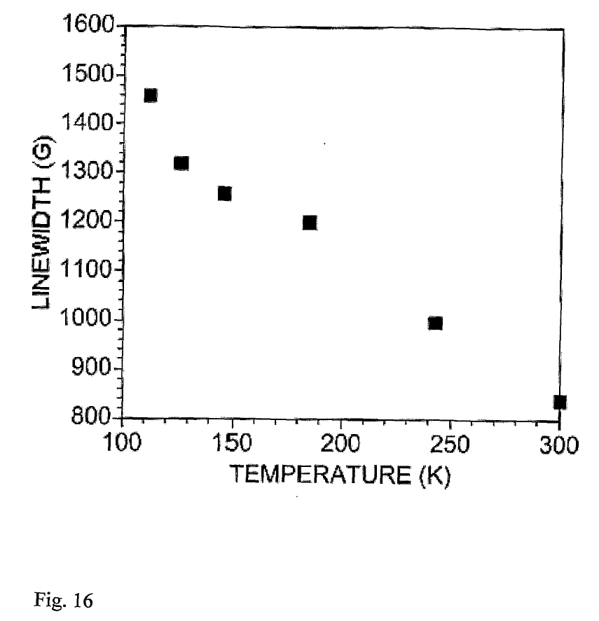

Similar measurements are showing similar behavior of Copper doped Gallium Nitride, Cu doped GaN. FIGS. 14 to 16 show corresponding data for Copper doped Gallium Nitride.

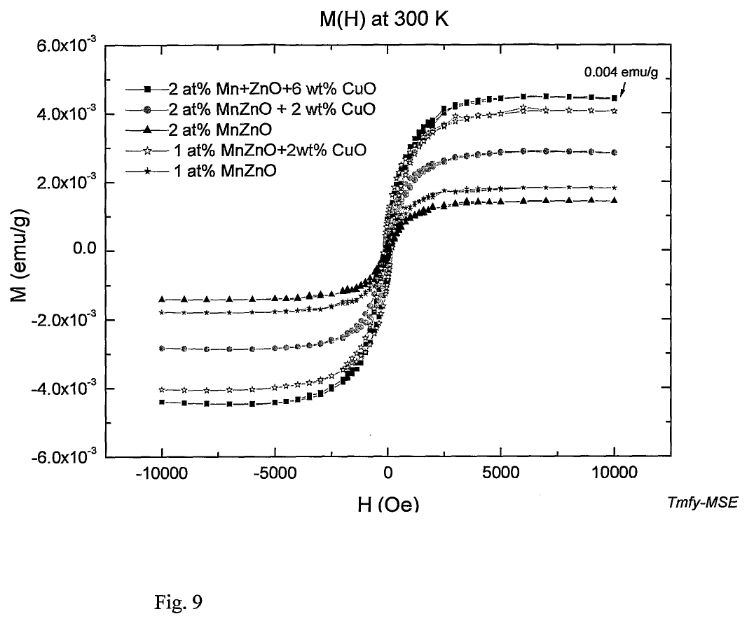

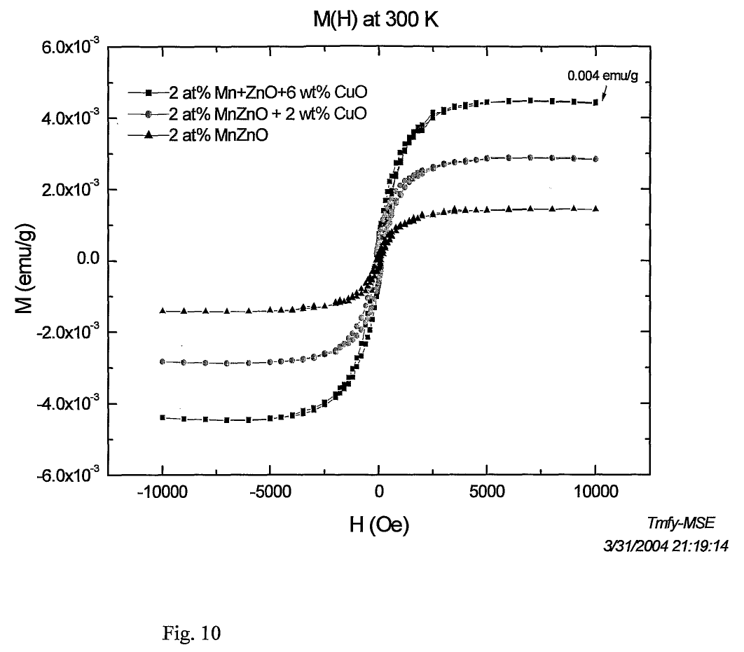

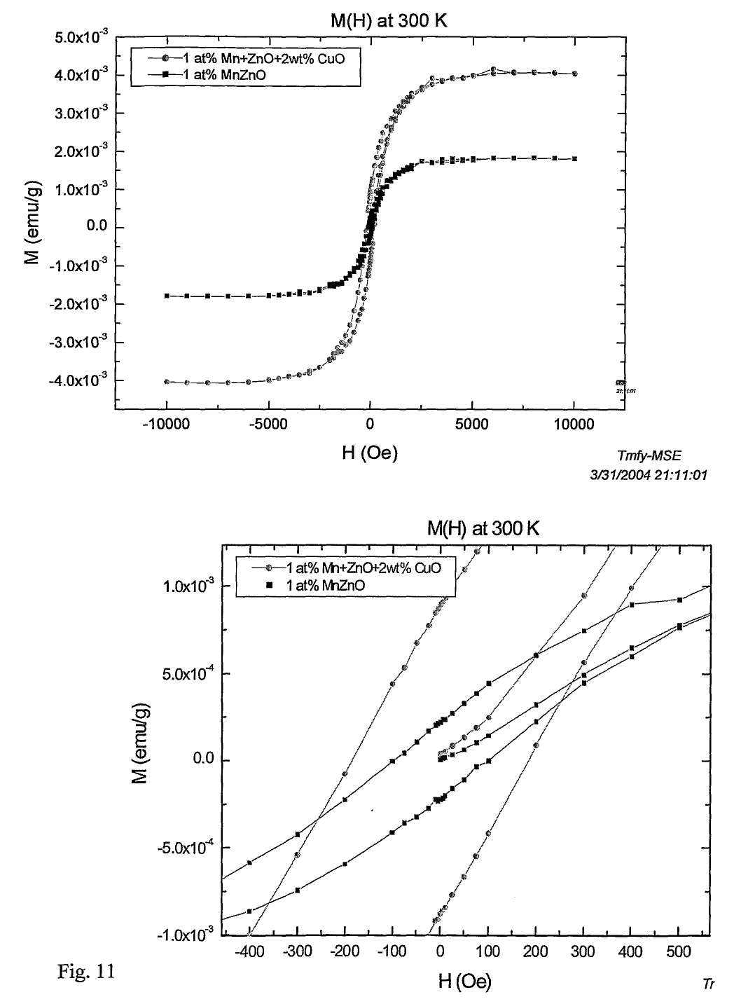

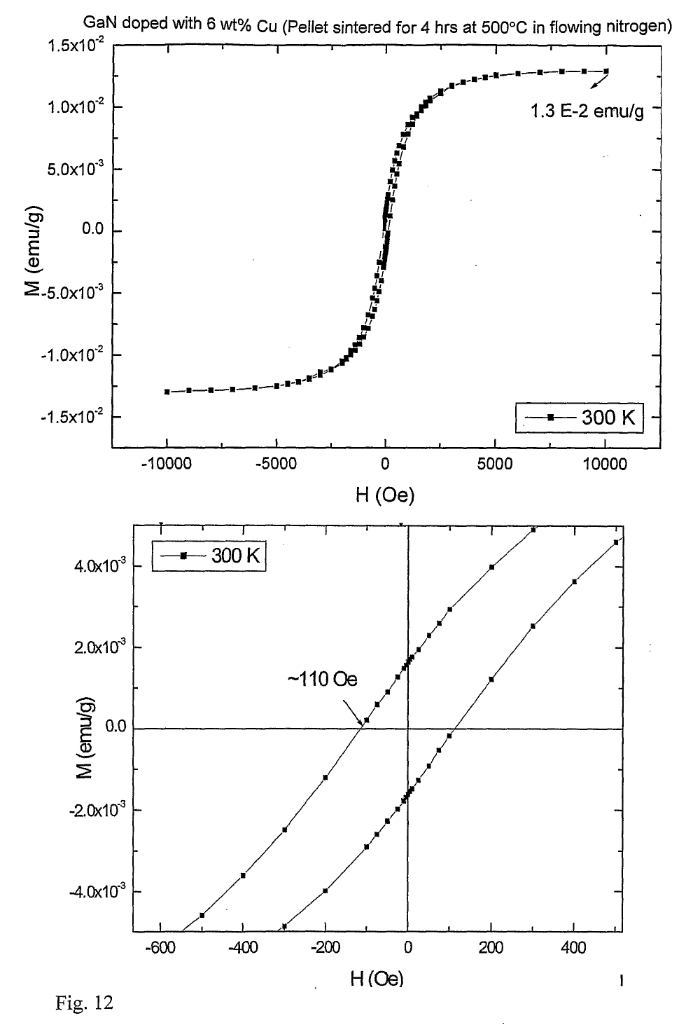

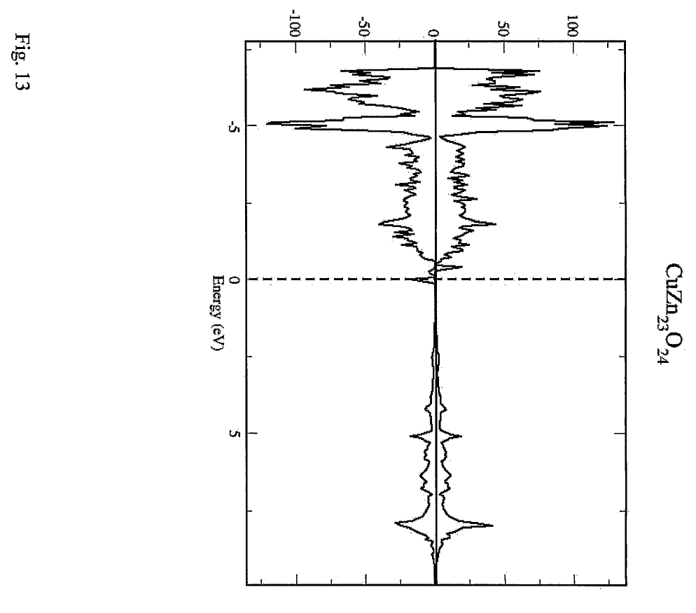

The inventions show also clearly the improvement of Copper doping of magnetic semiconductors as Manganese doped Zinc Oxide ZnMnO. The FIGS. 9, 10 and 11 show Squid measurements showing the doping effect with different concentrations of Copper doping in Mn doped ZnO with different concentrations of Manganese. We can from the figures see clear improvements of the ferromagnetic performance. FIG. 12 shows the the SQUID measurement of Copper doped Gallium Nitride. FIG. 13 shows data on Copper doped Zinc Oxide.

Preliminary measurements show similar behavior when Copper doping other magnetic semiconductors e.g. Mn doped CdS, Mn doped ZnS and Mn doped GaP.

### REFERENCES

1. Ohno, H. Making non magnetic semiconductors ferromagnetic. Science 281, 951 (1998)
2. Reed ,M. L. et al. Room temperature ferromagnetic properties of (Ga,Mn)N. Appl. Phys. Lett. 79, 3473 (2001)
3. Thaler, G. T. et. al. Mangetic properties of n-GaMnN thin films. Appl. Phys. Lett 80, 3964 (2002)
4. Theodoropoulou, N. et. al. Unconventional carrier mediated ferromagnetism above room temperature in ion implanted Ga,Mn)P:C .Phys. Rev Left 89 ,107203 (2002)
5. Sharma, P. et al. Ferromagnetism above room temperature in bulk and transparent thin films of Mn doped ZnO. Nature Materials 2, 673 (2003)
6. Dietl, T. et al. Model description of ferromagnetism in Zinc blend magnetic semiconductors. Science 287, 1019 (2000)
7. Knickelbein, M. Experimental observation of superparamagnetism in manganese clusters. Phys. Rev. Lett. 86 ,5255 (2001)
8. Rao, B. K. and Jena, P. Giant magnetic moments moments of nitrogen doped Mn clusters and their relevance in Mn doped GaN. Phys. Rev. Lett 89 185504 (2002)
9 Tanka, M et al. Epitaxial growth of ferromagnetic MnGa films with perpendicular magnetization on GaAs. Appl. Phys. Lett. 62, 1565 (1993)
10. Perlin, P. et. al. Investigation of longitudinal-optical phonon-plasma coupled modes in highly conducting bulk GaN. Appl. Phys. Lett 67 2524 (1995)
11. Vonsovkii, S. V. in Ferromagnetic Resonance edited by Vonsovki, S. V. P188-208 Pergamon Press, N.Y. 1966
12. Muraleedharan, K. et al. On the magnetic susceptibility of CuOx. Solid State Comm. 76, 727 (1990)
13. Sastry, M. D et. al. Low field microwave absorption in Gd2CuO4. Physica C170, 41(1990)
14. Owens, F. J. Resonant and non resonant microwave absorption study of ferromagnetic transition in RuSr2Gd0.5Eu0.5Cu2O8. Physica C353, 265 (2001).

1-7. (canceled)

8. A semi-conducting material being a non ferromagnetic material or a material having only a weak ferromagnetic component that is doped with copper, Cu, or Copper-oxide, CuO, thereby rendering the material ferromagnetic or amplifying its ferromagnetic component, at least at one temperature in the range between −55° C. and 125° C.

9. The semi-conducting material according to claim 8 wherein said doped semi conducting material comprises any of the following materials: Gallium Phosphide, GaP, doped with copper; Gallium Nitride, GaN, doped with copper; Gallium Arsenide, GaAs, doped with copper; Cadmium Sulphide, CdS, doped with copper; Cadmium Selenide, CdSe, doped with copper; Zinc Oxide, ZnO, doped with copper; Zinc Sulphide, ZnS, doped with copper; Zinc Selenide, ZnSe, doped with copper; Manganese doped with Zinc Oxide, ZnMnO, doped with copper; Manganese doped Cadmium Sulphide, CdMnS, doped with copper; Manganese doped Cadmium Sulphide, CdMnS, doped with copper; Manganese doped Cadmium Selenide, CdMnSe, doped with copper; Manganese doped Zinc Sulphide, ZnMnS, doped with copper; and Manganese doped Zinc Selenide, ZnMnSe, doped with copper.

10. A semi-conducting component wherein said component comprises the material according to claim 8.

11. The component according to claim 10 wherein said component is any of the following: a magnetic memory, a hard disc, a semi conducting magnetic memory, a MRAM, a spin valve transistor, a spin light emitting diode, a non-volatile memory, a logic device, an optical isolator, a sensor, and an ultra-fast optical switch.

12. A computer including a component according to claim 10.

13. A method for doping a semi conducting material being a non ferromagnetic material or a material having only a weak ferromagnetic component, the method comprising the following steps:
mixing said semi conducting material with Copper, Cu, or Copper oxide, CuO, in a chosen molecular weight ratio, forming a mixture,
grinding said mixture,
pressing the mixture to form pellets,
sintering said pellets at 500° C. for about four hours,
quenching said sintered pellets by cooling them to about room temperature.

14. The method according to claim 13, wherein said mixture is a mixture of, Copper Oxide, CuO and gallium phosphide, GaP in a molecular weight ratio of 0.003 to 1.

15. A semi-conducting component wherein said component comprises the material according to claim 9.

16. The component according to claim 15 wherein said component is any of the following:
a magnetic memory, a hard disc, a semi conducting magnetic memory, a MRAM, a spin valve transistor, a spin light emitting diode, a non-volatile memory, a logic device, an optical isolator, a sensor, and an ultra-fast optical switch.

17. A computer including a component according to claim 11.

18. A computer including a component according to claim 15.

19. A computer including a component according to claim 16.
